(19) United States
(12) Patent Application Publication
(10) Pub. No.: US 2015/0373841 A1
(43) Pub. Date: Dec. 24, 2015

(54) CORE AND PRINTED CIRCUIT BOARD

(71) Applicant: SAMSUNG ELECTRO-MECHANICS CO., LTD., Suwon-Si (KR)

(72) Inventors: Suk Hyeon CHO, Suwon-Si (KR); Yong Sam LEE, Yongin-Si (KR); Tae Hong MIN, Suwon-Si (KR); Young Gwan KO, Seoul (KR); Yoong OH, Suwon-Si (KR); Joon Sung LEE, Seoul (KR)

(21) Appl. No.: 14/746,308

(22) Filed: Jun. 22, 2015

(30) Foreign Application Priority Data
Jun. 23, 2014 (KR) 10-2014-0076604

(51) Int. Cl. H05K 1/02; C03B 33/02; H05K 3/00; H05K 1/03; H05K 1/11

(52) U.S. Cl. CPC H05K 1/0298; H05K 1/0306; H05K 1/115; H05K 1/038; H05K 3/0044; C03B 33/02; H05K 2203/0228

(57) ABSTRACT

A printed circuit board, according to one embodiment, includes: a core having a slope pattern formed on a side surface thereof; a first insulating layer laminated on the core; a second insulating layer laminated on the first insulating layer to cover the side surface of the core; an inner circuit layer and an outer circuit layer respectively formed on the first insulating layer and the second insulating layer; and a solder resist layer laminated on the second insulating layer.

### CROSS-REFERENCE TO RELATED APPLICATIONS

This application claims the foreign priority benefit under 35 U.S.C. Section 119 of Korean Patent Application No. 10-2014-0076604, filed Jun. 23, 2014, which is hereby incorporated by reference in its entirety into this application.

### BACKGROUND

1. Field

The present disclosure relates to a printed circuit board and a method of manufacturing the same, and more particularly, to a printed circuit board, which can form a predetermined pattern on a side surface of a glass core and prevent exposure of the side surface of the core, and a method of manufacturing the same.

2. Description of Related Art

In recent times, as the thickness of portable devices is being gradually decreased, there are efforts to reduce the entire thickness of internal components by manufacturing a thin substrate, on which a plurality of electronic components are mounted, with the thinning of the electronic components mounted inside the portable devices.

In particular, when manufacturing the thin substrate on which the plurality of electronic components are mounted, the substrate is exposed to a high temperature in a reflow process etc. during the manufacturing process of the substrate or during the mounting of the electronic components, and concave or convex warpage occurs due to the properties of materials during the repetition of high temperature processing and cooling.

In order to prevent the warpage of the substrate, there are efforts to increase the rigidity of raw materials used in the manufacturing process of the substrate and reduce the difference in the coefficient of thermal expansion (CTE) between the raw materials to improve the warpage due to the difference in the CTE in the reflow process, but the development of technology for preventing warpage is more needed.

Further, as a means to prevent warpage during the manufacturing process of the substrate by the improvement of a physical structure, a method of inserting a metal reinforcing member or a glass sheet into the substrate to increase the rigidity of a core material of the substrate is being considered, but it is difficult to process a through hole or a via since the metal core or the glass core has high rigidity, and even though the printed circuit board without warpage is manufactured, the core material is exposed to the side surface of the printed circuit board when the printed circuit board is cut.

And when the glass sheet is used as the core material, the printed circuit board is cut into unit printed circuit boards and commercialized after a via hole passing through the core material is formed or the strip type printed circuit board is manufactured. At this time, when a cutting means such as a blade or a wire saw passes through the glass sheet, fine cracks or chipping may occur on the cut surface, and the fine cracks may proceed to the internal cracks of the glass sheet during thermal processing.

### SUMMARY

One aspect of the present invention is to overcome the various disadvantages and problems raised in the conventional printed circuit board and to provide a printed circuit board in which the entire outer peripheral surface of a core is covered with an insulating layer.

Further, it is another aspect of the present invention to provide a printed circuit board in which a predetermined slope pattern is formed on a side surface of a glass core covered with an insulating layer.

In accordance with one aspect of the present invention, there is provided a core formed in a plate shape and having an upward slope and a downward slope alternately formed on a side surface thereof.

In accordance with another aspect of the present invention, there is provided a printed circuit board including: a core having a slope pattern formed on a side surface thereof; a first insulating layer laminated on the core; a second insulating layer laminated on the first insulating layer to cover the side surface of the core; an inner circuit layer and an outer circuit layer respectively formed on the first insulating layer and the second insulating layer; and a solder resist layer laminated on the second insulating layer.

The inner circuit layer and the outer circuit layer may be electrically connected through an interlayer via, and the outer circuit layer may be exposed through an opening formed in the solder resist layer.

The first insulating layer may be formed as a slope in the same direction as the slope pattern.

The first insulating layer may be made of an insulating material obtained by impregnating fabric cloth or glass cloth with a resin composition of resin or epoxy.

The slope pattern may be formed by alternately forming an upward slope, a downward slope, and a projecting slope.

In accordance with another aspect of the present invention, a printed circuit board comprises: a core having a sloped face on a side surface of the core; and an insulating layer covering the sloped face of the core. A method of manufacturing this printed circuit board comprises: forming groove portions in a glass sheet along a dicing line, thereby forming the sloped face from a surface of the glass sheet exposed by one of the formed groove portions; covering portions of the glass sheet exposed by the groove portions with the insulating layer; and cutting the glass sheet along the dicing line and through the groove portions.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view of a core in accordance with an embodiment of the present invention;

FIG. 2 shows cut perspective views of positions A through E of FIG. 1;

FIG. 3 is a perspective view of a printed circuit board in accordance with an embodiment of the present invention;

FIG. 4 is a partial perspective view showing a manufacturing method of the core in accordance with an embodiment of the present invention;

FIG. 5 is a plan view of the printed circuit board in accordance with an embodiment of the present invention before cutting, and

FIGS. 6A through 6D show cross-sectional views of positions I through IV, respectively, of FIG. 5.

### DESCRIPTION OF EMBODIMENTS

A matter regarding to an operational effect including a technical configuration for an object of a glass core and a printed circuit board using the same in accordance with the present invention will be clearly appreciated through the following detailed description with reference to the accompanying drawings showing embodiments of the present invention.

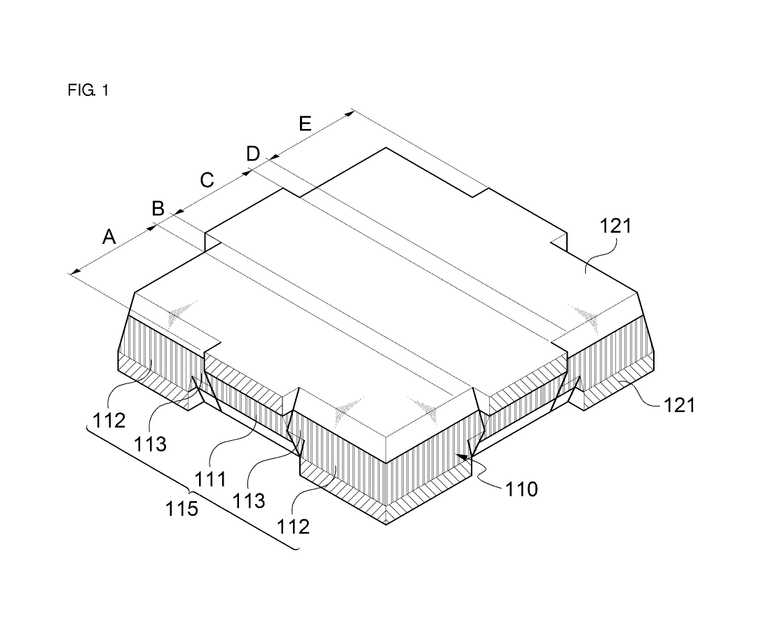

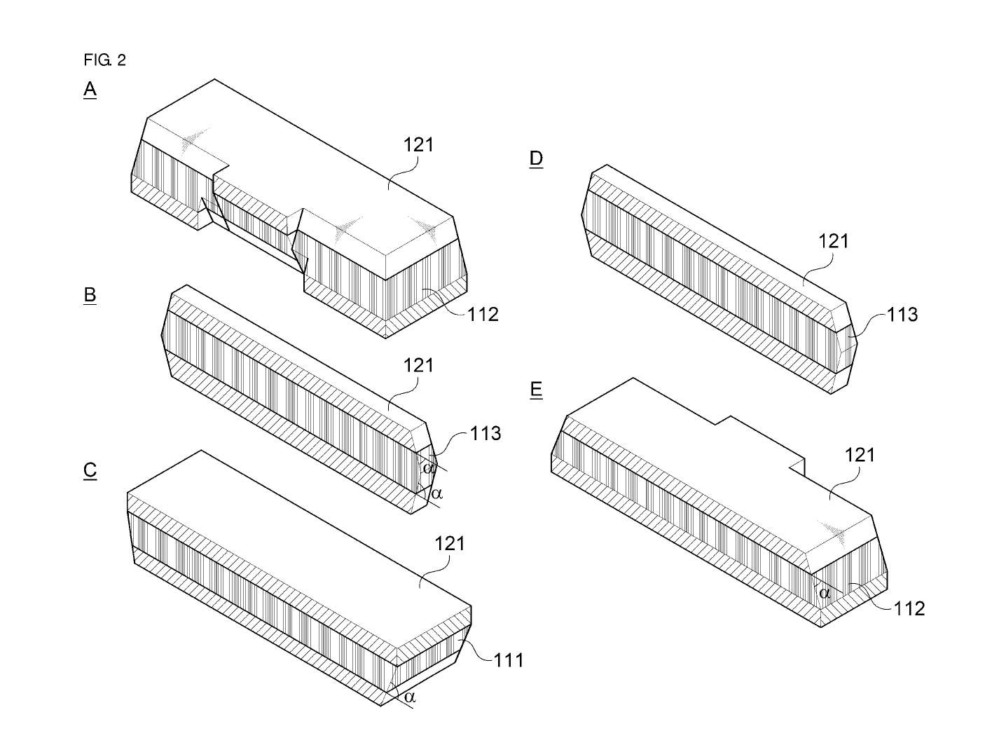

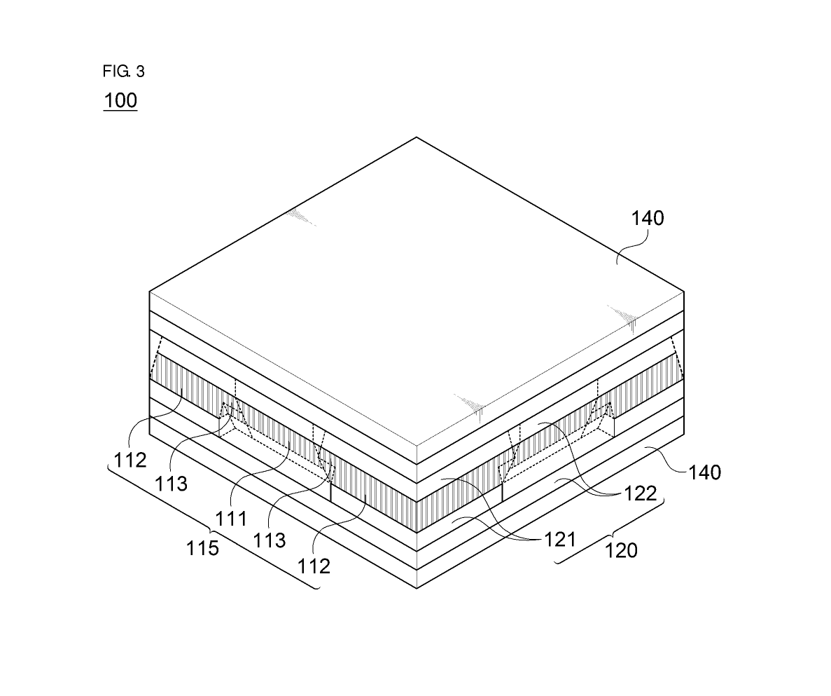

First, FIG. 1 is a perspective view of a core in accordance with an embodiment of the present invention, FIG. 2 shows cut perspective views of positions A through E of FIG. 1, and FIG. 3 is a perspective view of a printed circuit board in accordance with an embodiment of the present invention.

As shown, a printed circuit board 100 according to this embodiment may include a core 110 having a slope pattern 115 formed on a side surface thereof, an insulating layer 120 which covers the entire outer peripheral surface of the core 110 including the side surface of the core 110, an inner circuit layer 131 formed inside the insulating layer 120, and an outer circuit layer 132 formed on the insulating layer 120.

Further, a build-up layer (not shown in the drawing) may be further formed on the insulating layer 120 to be an interlayer structure of a multilayer printed circuit board, and the outer circuit layer 132 may be patterned on the build-up layer to be electrically connected to the inner circuit layer 131. At this time, the inner circuit layer 131 and the outer circuit layer 132 may be electrically connected through an interlayer via.

The insulating layer 120 may consist of first insulating layers 121 laminated on both surfaces of the core 110 and second insulating layers 122 laminated on the first insulating layers 121. A solder resist layer 140 may be covering an upper surface of the insulating layer 120 to protect the upper surface of the insulating layer 120 and a portion of the outer circuit layer 132 while forming the outermost layer of the printed circuit board. At this time, a pattern portion of the outer circuit layer 132 may be exposed to the outside through an opening of the solder resist layer 140.

The core 110, which forms a center portion of the printed circuit board 100, may be formed of a glass sheet in addition to an insulating material. Since the glass sheet forming the core 110 has a thickness of 25 μm to 200 μm, it is possible to prevent warpage by the rigidity of the glass material when laminating the insulating layers 120 on top and bottom of the core 110.

In other words, when the core 110 of the printed circuit board 100 is made of a resin composition, such as resin or epoxy, equal or similar to that of the insulating layer 120, excessive warpage may occur in a concave or convex direction by the heat and pressure applied in the lamination process of the insulating material which is an interlayer structure of the printed circuit board or by the difference in the coefficient of thermal expansion (CTE) between the resin composition and a metal material forming the pattern. In order to prevent this warpage, in the printed circuit board 100 of this embodiment, the glass core 110 may be applied to reduce the CTE of the core 110 and increase the rigidity of the core 110, thus significantly reducing warpage when laminating the insulating materials. This is because the glass core 110 can have a sufficient rigidity and a low CTE while being thin compared to the resin composition so that a thin printed circuit board can be manufactured while preventing warpage during a manufacturing process of the printed circuit board.

Further, the core 110 may be made of a glass material or prepreg (PPG) obtained by impregnating fabric cloth or glass cloth with a resin composition.

An insulating material, which serves as the first insulating layer 121, may be laminated on the outer peripheral surface of the core 110. The first insulating layer 121 may be made of an insulating material in which fabric cloth or glass cloth is impregnated with a resin composition while basically using the resin composition such as resin or epoxy and inorganic fillers such as nanowires are further included to adjust the CTE.

Meanwhile, as shown in FIG. 1, the core 110 having the first insulating layer 121 laminated thereon may have the slope pattern 115 on each side surface thereof. In the slope pattern 115 formed on the core 110, an upward slope 111 and a downward slope 112 may be alternately formed according to the position of the slope pattern 115. At this time, the upward slope 111 may be a slope inclined upward at an acute angle α with an extension of a lower surface of the core 110, and the downward slope 112 may be a slope inclined downward at an acute angle α with an extension of an upper surface of the core 110.

Further, a projecting slope 113, which is formed by bringing the upward slope and the downward slope into contact with each other in a center portion of the core 110, may be formed on the side surface of the core 110 between the upward slope 111 and the downward slope 112. The projecting slope 113 may be formed by bringing the slopes, which are respectively inclined upward and downward at an acute angle α with the extension of the upper and lower surfaces of the core 110, into contact with each other in the center portion of the core 110.

The projecting slope 113 may be formed at the same time during the formation of the upward slope 111 and the downward slope 112. The projecting slope 113 may be formed by overlapping the slopes with each other when the upward slope 111 and the downward slope 112 are formed in the adjacent positions.

The first insulating layers 121 may be laminated on the upper and lower surfaces of the core 110. The first insulating layer 121 may be processed at the same time during the formation of the slope pattern 115 of the core 110 to be formed as a slope in the same slope direction as the slopes of the core 110.

The upward slope 111, the downward slope 112, and the projecting slope 113 of the core 110 may be formed by forming groove portions in upper and lower surfaces of the glass sheet.

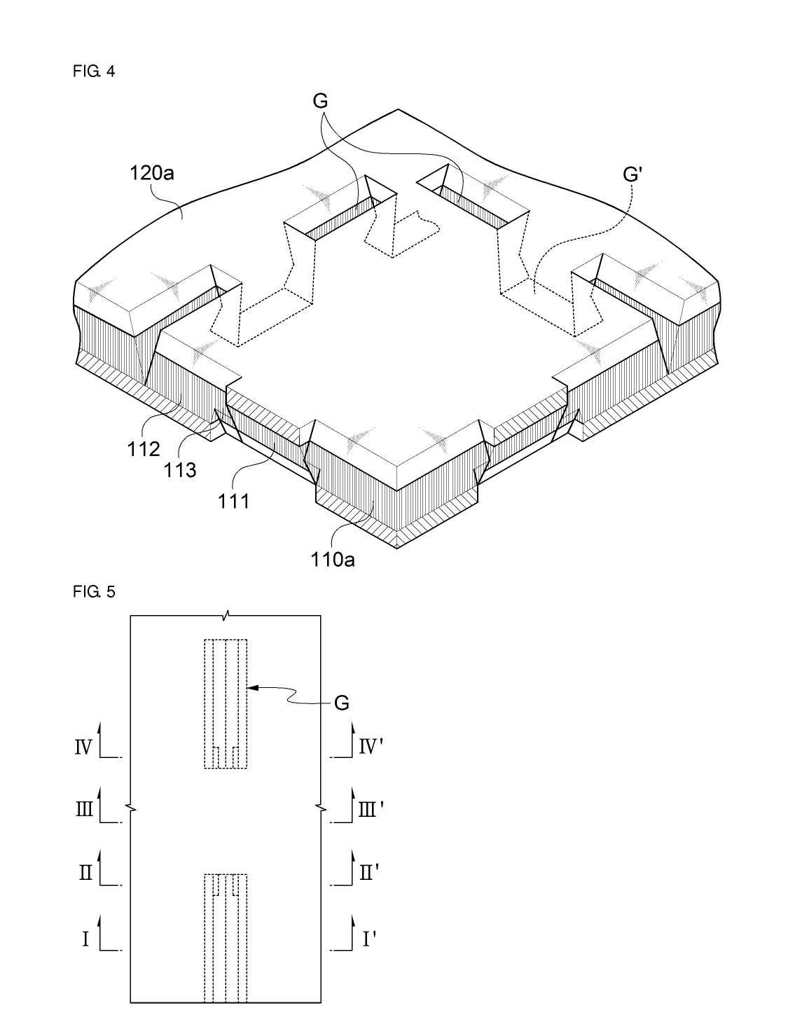

The process of forming the slope pattern of the core will be described in detail below with reference to FIG. 4.

FIG. 4 is a partial perspective view showing a manufacturing method of the core according to embodiments of the present invention. As shown, the core 110 may be manufactured by cutting a plate type core sheet 110a to a predetermined size. Insulating materials 120a may be laminated on upper and lower surfaces of the core sheet 110a, respectively. The insulating material 120a laminated on the core sheet 110a may serve as the first insulating layer 121 of the printed circuit board 100 in FIG. 1.

Groove portions G may be formed at regular intervals on the upper and lower surfaces of the core sheet 110a having the insulating materials 120a laminated thereon to be applied as a dicing line. At this time, the groove portions G formed on the core sheet 110a may be processed on the upper and lower surfaces of the core sheet 110a, respectively. Further, the groove portions G may be formed to have a predetermined angle of inclination using a diamond saw or a laser drill. And the groove portions G may be formed by chemical etching.

More specifically, the groove portions G may be formed on the upper and lower surfaces of the core sheet 110a, on which the insulating materials 120a are laminated, in a row at regular intervals. The groove portions G may be processed on the upper and lower surfaces of the core sheet 110a so that both ends of the groove portion G formed on the upper surface of the core sheet 110a and the groove portion G′ formed on the lower surface of the core sheet 110a may be partially overlapped with each other.

At this time, the groove portions G may be formed on the core sheet 110a, on which the insulating materials 120a are laminated, at equal intervals. The groove portion G formed on the upper surface of the core sheet 110a may be formed not to pass through the insulating material 120a laminated on the lower surface of the core sheet 110a, and the groove portion G′ formed on the lower surface of the core sheet 110a may be formed not to pass through the insulating material 120a laminated on the upper surface of the core sheet 110a.

Therefore, the groove portions G and G′ may be entirely formed along the dicing line including the position in which the groove portions G and G′ formed on the upper and lower surfaces of the core sheet 110a cross each other, but the core sheet 110a may be supported by the unprocessed insulating material 120a between the groove portions G and G′ to prevent the separation of the core 110.

Like this, the groove portions G and G′ formed on the upper and lower surfaces of the core sheet 110a may be formed in a lattice shape, and the core sheet 110a may be cut along the dice line formed along the groove portions G and G′ to manufacture the core 110 in which the upward slope 111, the downward slope 112, and the projecting slope 113 are alternately formed on the side surface thereof as shown in FIG. 1.

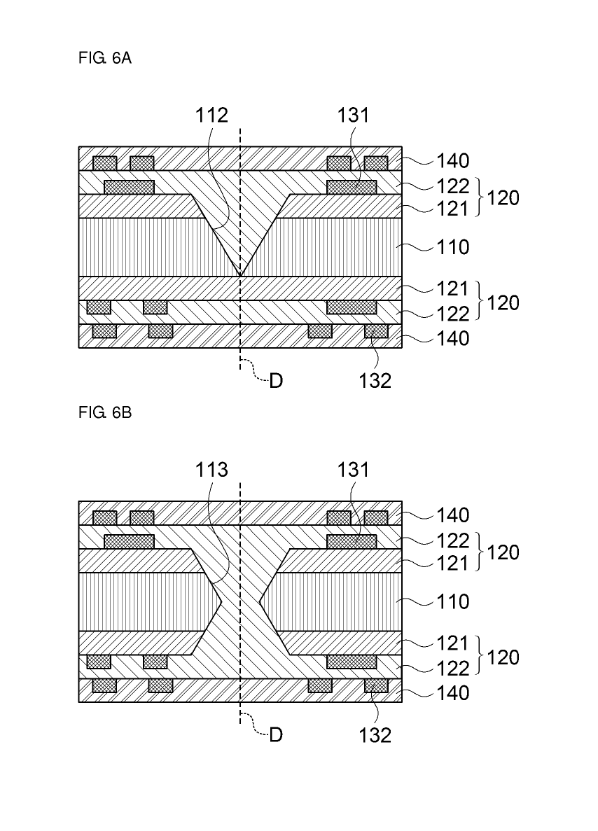

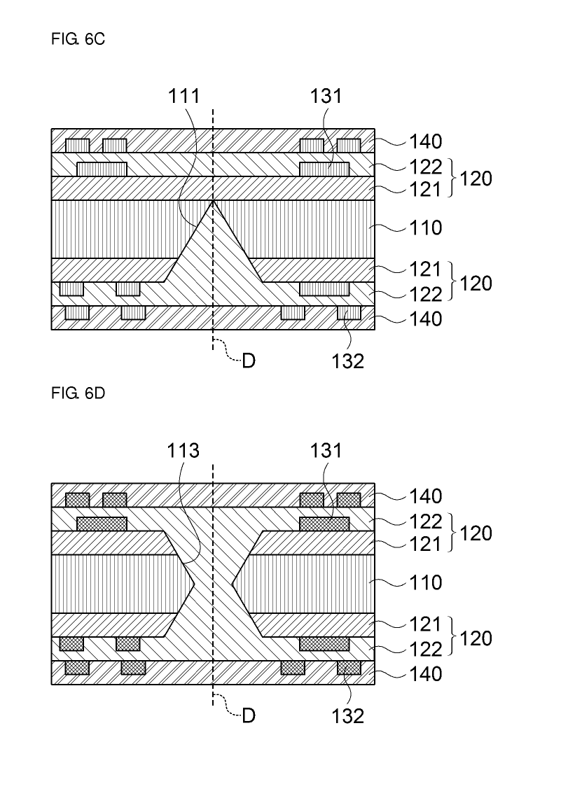

Meanwhile, the printed circuit board 100 as in FIG. 3 may be manufactured by forming the build-up layer and the circuit layer on the upper and lower surfaces of the core 110 shown in FIG. 1. A structure of the printed circuit board shown in FIGS. 5 and 6 will be described in detail with reference to FIG. 3.

FIG. 5 is a plan view of the printed circuit board of embodiments of the present invention before cutting, and FIG. 6 shows cross-sectional views of positions I through IV of FIG. 5. Here, FIGS. 5 and 6 are views showing the state in which a plurality of printed circuit boards are arranged in an array form before being manufactured into the printed circuit board shown in FIG. 3.

As shown in FIGS. 5 and 6 in addition to FIG. 3, in the printed circuit board 100 of this embodiment, the first insulating layer 121 and the second insulating layer 122, which are defined as the insulating layer 120, may be laminated on the core 110 having the slope pattern 115 formed on the side surface thereof, and the solder resist layer 140 may be formed on the insulating layer 120. The inner circuit layer 131 and the outer circuit layer 132 may be formed on the first insulating layer 121 and the second insulating layer 122, respectively, and the first insulating layer 121 and the second insulating layer 122 may be electrically connected through a via (not shown in the drawing).

Further, FIGS. 6A-6D show cross-sectional shapes of the positions I through IV, respectively, based on the groove portion G formed on the core sheet 110a in a state in which the insulating layer 120 and the solder resist layer 140 are laminated. In the cross section I-I′, the groove portion G having the downward slope 112 may be formed on the core 110, and in the cross sections II-II′ and IV-IV′, the projecting slope 113, which is formed by bringing the upward slope and the downward slope into contact with each other in the center portion of the core, is formed. Further, in the cross section III-III′, the groove portion G′ having the upward slope 111 may be formed on the lower surface of the core 110.

The printed circuit boards, which are arranged in an array form as above, may be cut along the dicing line D of the groove portion G to be formed into the unit printed circuit board 100 as in FIG. 3. At this time, referring to FIG. 3, the slope pattern 115 may be formed on the side surface of the core 110, and the insulating layer 120 may cover the entire side surface of the core 110 to prevent the side surface of the core 110 from being exposed to the outside.

Further, the side surface of the core 110 may be cut in advance by the groove portion G on the sheet type core sheet 110a, the second insulating layer 122 of the insulating layer 120 may be filled in the cut position, and the insulating layer 120 may be cut to prevent the side surface of the core 110 from being exposed to the outside of the insulating layer 120.

Accordingly, fine cracks or chipping of the side surface of the glass core 110 can be prevented by preventing the direct contact between the side surface of the core 110 and a cutting means when mainly cutting the glass core 110 having rigidity.

As described above, the printed circuit board according to embodiments of the present invention can prevent the fracture or fine cracks of the core in the printed circuit board by preventing the direct contact between the cut side surface of the core and the cutting means to prevent stress generated during cutting from being transmitted to the core.

Further, the printed circuit board according to embodiments of the present invention can prevent the side surface of the core from being exposed to the outside.

The above-described embodiments of the present invention are disclosed for the purpose of exemplification and it will be appreciated by those skilled in the art that various substitutions, modifications and variations may be made in these embodiments without departing from the technical spirit of the present invention. Such substitutions and modifications are intended to be included in the appended claims.

What is claimed is:

1. A core formed in a plate shape and having an upward slope and a downward slope alternately formed on a side surface thereof.

2. The core according to claim 1, wherein a projecting slope is further formed between the upward slope and the downward slope, and the upward slope and the downward slope are in contact with each other in a center portion of the side surface of the core.

3. The core according to claim 1, wherein the upward slope is a slope inclined upward at an acute angle with an extension of a lower surface of the core.

4. The core according to claim 1, wherein the downward slope is a slope inclined downward at an acute angle with an extension of an upper surface of the core.

5. The core according to claim 1, wherein the core is made of a glass material.

6. The core according to claim 1, wherein the core is coated with an insulating material containing fabric cloth or glass cloth impregnated with a resin composition of resin or epoxy.

7. A printed circuit board comprising:
a core having a slope pattern formed on a side surface thereof;
a first insulating layer laminated on the core;
a second insulating layer laminated on the first insulating layer to cover the side surface of the core;
an inner circuit layer and an outer circuit layer respectively formed on the first insulating layer and the second insulating layer; and
a solder resist layer laminated on the second insulating layer.

8. The printed circuit board according to claim 7, wherein the inner circuit layer and the outer circuit layer are electrically connected through an interlayer via, and the outer circuit layer is exposed through an opening formed in the solder resist layer.

9. The printed circuit board according to claim 7, wherein the first insulating layer is formed as a slope in the same direction as the slope pattern.

10. The printed circuit board according to claim 9, wherein the first insulating layer is made of an insulating material containing fabric cloth or glass cloth impregnated with a resin composition of resin or epoxy.

11. The printed circuit board according to claim 7, wherein the slope pattern is formed by alternately forming an upward slope, a downward slope, and a projecting slope.

12. The printed circuit board according to claim 11, wherein the projecting slope is formed between the upward slope and the downward slope, and the upward slope and the downward slope are in contact with each other in a center portion of the side surface of the core.

13. The printed circuit board according to claim 12, wherein the upward slope is a slope inclined upward at an acute angle with an extension of a lower surface of the core.

14. The printed circuit board according to claim 12, wherein the downward slope is a slope inclined downward at an acute angle with an extension of an upper surface of the core.

15. The printed circuit board according to claim 7, wherein the core is made of a glass material.

16. A printed circuit board comprising:
a core having a sloped face on a side surface of the core; and
an insulating layer covering the sloped face of the core.

17. The printed circuit board according to claim 16, wherein the sloped face is an upward or downward slope that is extant across a substantially entire distance from an edge of an upper surface of the core to an edge of a lower surface of the core.

18. The printed circuit board according to claim 17, wherein the core is made of a glass material, further comprising:
a plurality of downward-sloping faces and upward-sloping faces on the side surface of the core, each of the downward-sloping faces and upward-sloping faces covered by the insulating layer, and one of the downward-sloping faces and one of the upward-sloping faces intersecting with each other so as to form an angled protrusion therebetween;
upper and lower build-up insulating layers formed respectively on upper and lower surfaces of the core; and
upper and lower circuit layers formed respectively on the upper and lower build-up insulating layers, the upper and lower circuit layers electrically connected to each other through an interlayer via.

19. A method of manufacturing the printed circuit board of claim 16, comprising:
forming groove portions in a glass sheet along a dicing line, thereby forming the sloped face from a surface of the glass sheet exposed by one of the formed groove portions;
covering portions of the glass sheet exposed by the groove portions with the insulating layer; and
cutting the glass sheet along the dicing line and through the groove portions.
